(19) United States
(12) Patent Application Publication
(10) Pub. No.: US 2009/0209066 A1
(43) Pub. Date: Aug. 20, 2009

(54) DIE BONDING METHOD AND DIE BONDER

(75) Inventor: Kazuma Sekiya, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/363,489

(22) Filed: Jan. 30, 2009

(30) Foreign Application Priority Data
Feb. 14, 2008 (JP) 2008-032931

(51) Int. Cl. H01L 21/78; B32B 38/00

(52) U.S. Cl. 438/114; 156/494; 257/E21.599

(57) ABSTRACT

In a die bonding method, a bonding film is stuck to a rear surface of a wafer and to a dicing tape stuck to a dicing frame. The wafer is thus supported by the dicing frame. Predetermined dividing lines are completely cut and the bonding film is incompletely cut to leave a cut-residual portion. The dicing tape is stretched to break the cut-remaining portion. The die to which the bonding film is stuck is picked up from the dicing tape and bonded to a mount-targeted substrate.

### BACKGROUND OF THE INVENTION

1. Field of the Invention

The present invention relates to a method of bonding a die with a bonding film stuck to the rear surface thereof, and a die bonder usable to execute the method.

2. Description of the Related Art

A wafer in which a plurality of dice formed with ICs, LSIs or the like and sectioned by streets are formed on the front surface thereof is cut along the streets by a dicing device, a laser processing machine or the like into individual dice, which are widely used in various electronic devices. A bonding film is stuck to the rear surface of the wafer that has not yet divided into the dice. By cutting the streets along with the bonding film, the dice are formed that have the bonding films stuck to the rear surfaces thereof. The dice are each bonded through the bonding film to a mount-targeted substrate such as a lead frame or the like.

Incidentally, if the bonding film is cut together with the wafer using a cutting device, it causes burrs, which pose a problem of producing disconnection of a wire during wire bonding. On the other hand, if the bonding film is cut together with the wafer using a laser processing machine, it is melt and deposited to the dicing tape, which poses a problem in that the die cannot be picked up.

To solve such problems, the present applicant proposed the following technology and applied for a patent. In a cutting step using a cutting device or a laser processing machine, a wafer is completely cut along a street, whereas a bonding film stuck to the rear surface of the wafer is incompletely cut to leave a cut-residual portion. This prevents the bonding film from causing burrs, and from being melted. Thereafter, the dicing tape is stretched so that the cut-residual portions are broken to divide the wafer into individual dice. See e.g. Japanese Patent Laid-open No. 2007-294651.

However, although the dicing tape is stretched to divide all the dice into the individual pieces, the dice remaining stuck to the dicing tape may thereafter be stored in a wafer cassette or the like and time may pass. Such a case poses a problem in that the bonding films adjacent to each other adhere to each other so that the die cannot be picked up from the dicing tape in a die-bonding step.

### SUMMARY OF THE INVENTION

Accordingly, it is an object of the present invention to provide a die bonding method capable of smoothly picking up a die from a dicing tape by preventing adhesion of boding films stuck to respective adjacent dice after stretch of the dicing tape, when the die with the bonding film stuck to the rear surface thereof is picked up for die bonding.

In accordance with an aspect of the present invention, there is provided a die bonding method of bonding a die having a bonding film on a rear surface thereof to a substrate, including: a bonding film sticking step of sticking the bonding film to a rear surface of a wafer in which a plurality of the dice are formed and sectioned by predetermined dividing lines; a support step of sticking the bonding film to a dicing tape whose outer circumferential portion is stuck to a dicing frame to support the wafer by the dicing frame; a cutting step of completely cutting the predetermined dividing line and incompletely cutting the bonding film to leave a cut-residual portion; a breaking step of stretching the dicing tape to break the cut-residual portion of the bonding film; a picking-up step of picking up from the dicing tape the die to which the bonding film is stuck; and a die bonding step of bonding the die thus picked up to the substrate.

For example, a cutting blade or a laser beam can be used in the cutting step. It is preferable that the cut-residual portion of the bonding film have a thickness of 20 μm or less in the cutting step. It is preferable that the bonding film be cooled to 10° C. or lower in the die bonding step.

In accordance with another aspect of the present invention, there is provided a die bonder for picking up and bonding a die to a mount-targeted substrate, the die having a bonding film stuck to a rear surface thereof and supported by a dicing frame to which the bonding film is stuck, including: frame supporting means for supporting the dicing frame; tape stretching means for stretching the dicing tape to break the bonding film; cooling means for cooling the bonding film; a picking-up and bonding portion for picking-up from the stretched dicing tape the die to which the bonding film is stuck and bonding the die to the mount-targeted substrate.

In the present invention, the predetermined dividing line of the wafer is completely cut in the cutting step, whereas the bonding film is incompletely cut to leave the cut-residual portion. In the die bonding step, the dicing tape is stretched to break the cut-residual portions. In this way, the wafer is divided into individual dice and die bonding is performed. Thus, the problem can be solved in that the bonding films stuck to the adjacent dice adhere to each other so that the die cannot be picked up.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is an exploded perspective view illustrating a wafer, a bonding film, and a dicing tape with a dicing frame stuck thereto;

FIG. 2 is a perspective view illustrating a cutting device by way of example;

FIG. 3 is a partially enlarged cross-sectional view illustrating the wafer and bonding film after completion of a cutting step;

FIG. 4 is a partial perspective view of a die bonder by way of example;

FIG. 5 is a schematic cross-sectional view illustrating a state where a die is held in the die bonder;

FIG. 6 is a schematic cross-sectional view illustrating a state where the dicing tape is stretched by the die bonder; and

FIG. 7 is an explanatory view illustrating from picking up a die to die bonding.

### DETAILED DESCRIPTION OF THE PREFERRED EMBODIMENTS

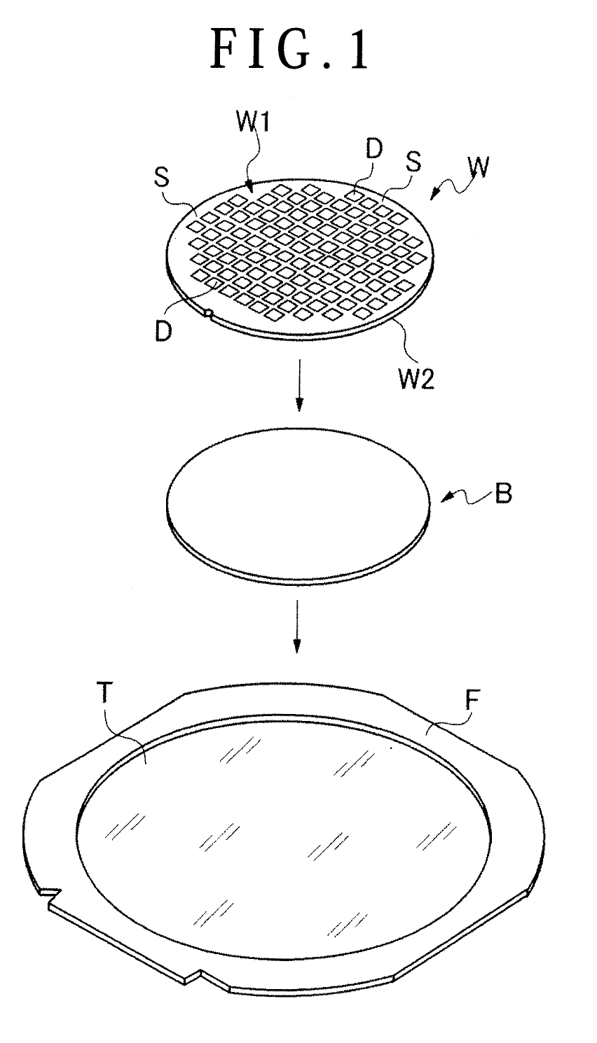

Referring to FIG. 1, a front surface W1 of a wafer W is sectioned along predetermined dividing lines (streets) S into a plurality of dice D formed with integrated circuits. A bonding film B for die-bonding is stuck to a rear surface W2 of the wafer W. This bonding film B is a film-like adhesive material called a die-attach film. For example, the bonding film B is composed of a mixture of an epoxy-based resin with an acryl-base resin and has a thickness of about 30 to 100 μm. In addition, the bonding film B can be stuck to the rear surface W2 of the wafer W by being heated and pressed thereto.

The bonding film B stuck to the wafer W is next stuck to the adherent surface of a dicing tape T. A ringlike dicing frame F is stuck to the outer circumferential portion of the adherent surface of the dicing tape T. Thus, the wafer W is stuck to the dicing tape T so as to be supported by the dicing frame F via the dicing tape T.

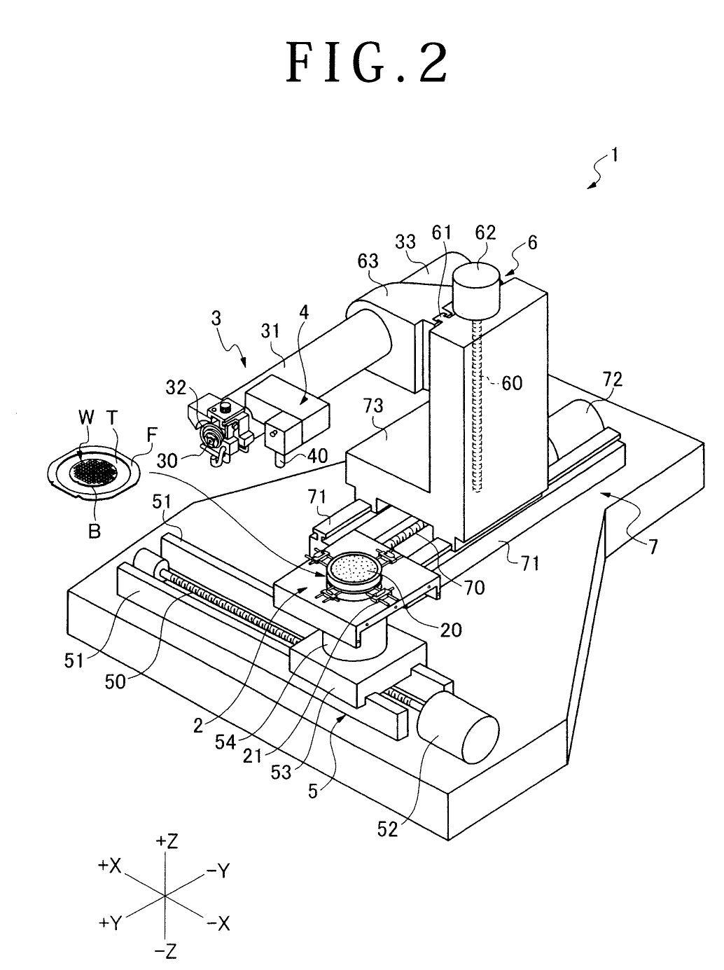

The predetermined dividing lines S of the wafer W is next cut using e.g. a cutting device 1 shown in FIG. 2. This cutting device 1 includes a chuck table 2 adapted to hold the wafer and cutting means 3 for cutting the wafer held on the chuck table 2. The chuck table 2 includes a holding surface 20 adapted to suck and hold the wafer W via the dicing tape T and securing portions 21 adapted to secure the dicing frame F.

The cutting means 3 includes a spindle 30 having a Y-axial shaft center; a housing 31 for rotatably supporting the spindle 30; a cutting blade 32 attached to the spindle 30; and a motor 33 for drivingly rotating the spindle 30. An alignment means 4 is secured to a lateral portion of the housing 31 to detect a position of the wafer to be cut and align the cutting blade 32 with such a position. The alignment means 4 is equipped with an imaging means 40 for picking up an image of the front surface of the wafer held on the chuck table 2.

The chuck table 2 is cutting-transferred in an X-axial direction by a cutting-transfer means 5. The cutting-transfer means 5 includes a ball screw 50 having an X-axial shaft center; a pair of guide rails 51 disposed parallel to the ball screw 50; a motor 52 connected to one end of the ball screw 50; a travel base 53 whose inside nut is engaged with the ball screw 50 and whose lower portion is in slidable contact with the guide rails 51; and a turning drive portion 54 secured to the travel base 53 to turn the chuck table 2. With such a configuration, as the motor 52 is driven to turn the ball screw 50, the travel base 53 and the turning drive portion 54 are moved in the X-axial direction while being guided by the guide rails 51.

The cutting means 3 can be move in a Z-axial direction by an incision-transfer means 6 and in the Y-axial direction by an index-transfer means 7. The incision-transfer means 6 includes a ball screw 60 disposed to extend in the Z-axial direction; a pair of guide rails 61 disposed parallel to the ball screw 60; a pulse motor 62 connected to one end of the ball screw 60; and a support portion 63 which supports the cutting means 3, whose inside nut is screwed with the ball screw 60 and whose lateral portion is in slidable contact with the guide rails 61. As the ball screw 60 is driven by the pulse screw 62 to turn, the support portion 63 is moved upward and downward along with the cutting means 3 while being guided by the guide rails 61.

The index-transfer means 7 includes a ball screw 70 disposed to extend in the Y-axial direction; a pair of guide rails 71 disposed parallel to the ball screw 70; a pulse motor 72 connected to one end of the ball screw 70; and a travel base 73. This travel base 73 is provided with the ball screw 60 and the guide rails 61 in and on its lateral surface section. The travel base 73 is provided with the pulse motor 62 on its upper portion. The travel base 73 has an inside nut screwed with the ball screw 70 and a lower portion in slidable contact with the guide rails 71. With such a configuration, as the ball screw 70 is driven by the pulse motor 72 to turn, the travel base 73 is moved in the Y-axial direction along with the Y-axial movement of the cutting means 3 while being guided by the guide rails 71.

The wafer W to be subjected to dicing is held on the holding surface of the chuck table 2 while being supported integrally with the dicing frame F, which is secured to the securing portion 21. The wafer W is held on the chuck table 2 in this way. The cutting-transfer means 5 drives the chuck table 2 in a +X-direction to thereby move the wafer W to a position immediately below the imaging means 40. Here, the alignment means 4 detects a predetermined dividing line S to be cut and Y-axially aligns the cutting blade 32 therewith. Further, the chuck table 2 is moved in the same direction and while being rotated at high-speed, the cutting blade 32 is driven by the incision-transfer means 6 to lower the cutting means 3, which cuts the predetermined dividing line S detected.

The same cutting is performed while the cutting means 3 is indexing-transferred by the indexing-transfer means 7 by the interval between the predetermined determined lines S. Thus, all the predetermined dividing lines S of the same direction are completely cut. Further, the chuck table 2 is turned by 90 degrees before the same cutting is performed to cut all the predetermined dividing lines S.

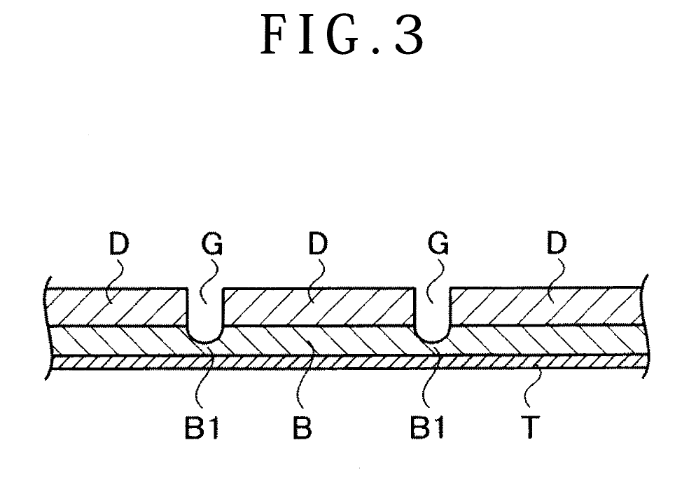

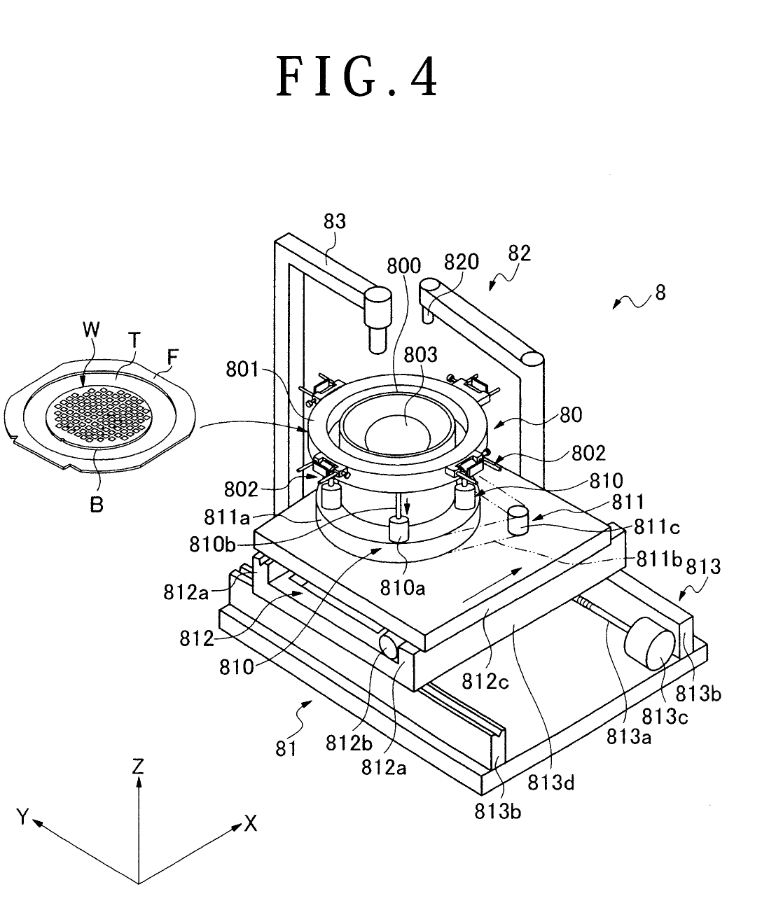

During the cutting performed as described above, the cutting-transfer means 6 precisely controls the incision-depth of the cutting blade 32. Under such control, as shown in FIG. 3, the predetermined dividing lines S of the wafer W are completely cut to form cut-grooves G that passes through the front and rear surfaces; however, the bonding film B is incompletely cut to leave cut-residual portions B1. For example, the cut-residual portion B1 is made to have a thickness of 20 μm or less. Incidentally, a laser processing machine can be used to irradiate the predetermined dividing line S with a laser beam to execute the cutting step. After the completion of the cutting step, the wafer W is conveyed to a die bonder 8 shown in e.g. FIGS. 4 through 7, the wafer W being supported by the dicing frame F via the dicing tape T and maintaining a wafer shape as a whole even after the cutting.

Referring to FIG. 4, the die bonder 8 includes a placing portion 80 on which the wafer W united with the dicing frame F via the dicing tape T is placed; a drive portion 81 for removing the placing portion 80; a pickup bonding portion 82 for picking up a die with a suction portion 820 and bonding it on a mount-targeted substrate; and a die detection portion 83 for detecting a die to be picked up through imaging.

The placing portion 80 includes a cylindrical die support base 800 for supporting from below the wafer W via the dicing tape T; a frame support means 801 for supporting the dicing frame F from below; a plurality of frame securing portions 802 arranged on the outer lateral surface of the frame support means 801 to secure the dicing frame F thereto; and a cooling means 803 disposed inside the die support base 800 to cool a workpiece supported by the die support base 800.

The drive portion 81 includes a plurality of a lifting drive portion 810 for moving up and down the frame support means 801; a turning drive portion 811 for turning the placing portion 80; an X-axial drive portion 812 for moving the placing portion 80 in the X-axial direction; and a Y-axial drive portion 813 for moving the placing portion 80 in the Y-axial direction perpendicular to the X-axial direction. The lifting drive portion 810 includes an air cylinder 810a and a piston 810b. An upper end of the piston 810b is secured to the frame support means 801. With such a configuration, the piston 810b is moved upward and downward to move the frame support means 801 upward and downward.

The turning drive portion 811 includes a turn table 811a to which the air cylinders 810a and the die support base 800 are secured; a belt 811b wound around the outer circumference of the turn table 811a; and a drive source 811c for driving the belt 811b to turn the turn table 811a. With such a configuration, the turn table 811a is turned to turn the die support base 800, the lifting drive portion 810 and the frame support means 801.

The X-axial drive portion 812 includes a ball screw not shown having an X-axial shaft center; guide rails 812a disposed parallel to the ball screw; a pulse motor 812b for turning the ball screw; and an X-axial traveling base 812c whose inside nut, not shown, screwed with the ball screw and whose lower portion is in slidable contact with the guide rails 812a. With such a configuration, as the ball screw is driven by the pulse motor to turn, the X-axial traveling base 812c is moved in the X-axial direction while being guided by the guide rails 812a.

The Y-axial drive portion 813 includes a ball screw 813a having a Y-axial shaft center; guide rails 813b disposed parallel to the ball screw 813a; a pulse motor 813c for turning the ball screw 813a; and an Y-axial traveling base 813d whose inside nut, not shown, screwed with the ball screw 813a and whose lower portion is in slidable contact with the guide rails 813b. With such a configuration, as the ball screw 813a is driven by the pulse motor 813c to turn, the Y-axial traveling base 813d is moved in the Y-axial direction while being guided by the guide rails 813b.

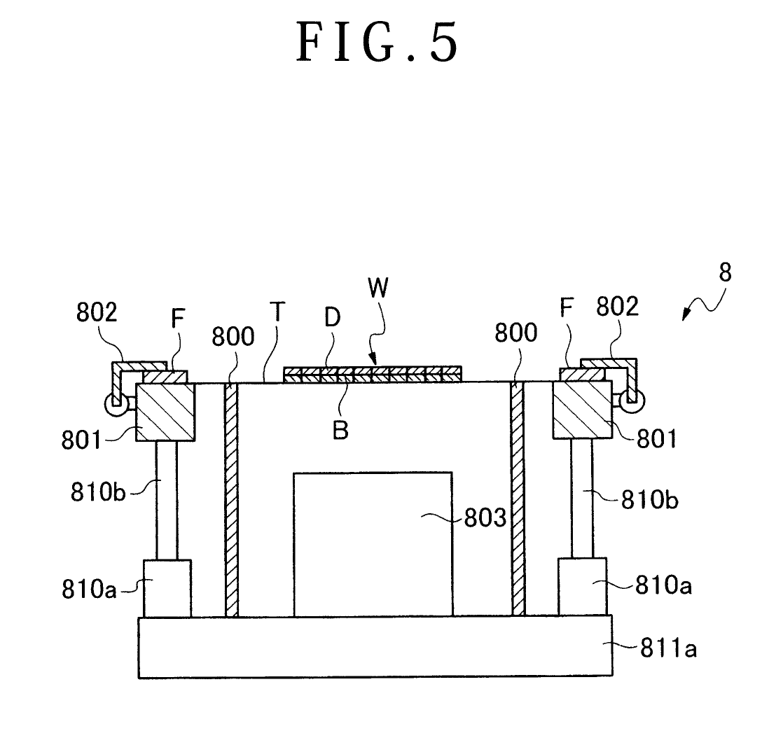

Referring to FIG. 5, the plurality of dice D supported by the dicing frame F via the dicing tape T are placed on the die support base 800 of the pickup device 8 while maintaining a wafer shape as a whole. On the other hand, the dicing frame F is placed on the frame support means 801 and fixedly pressed against the frame securing portions 802.

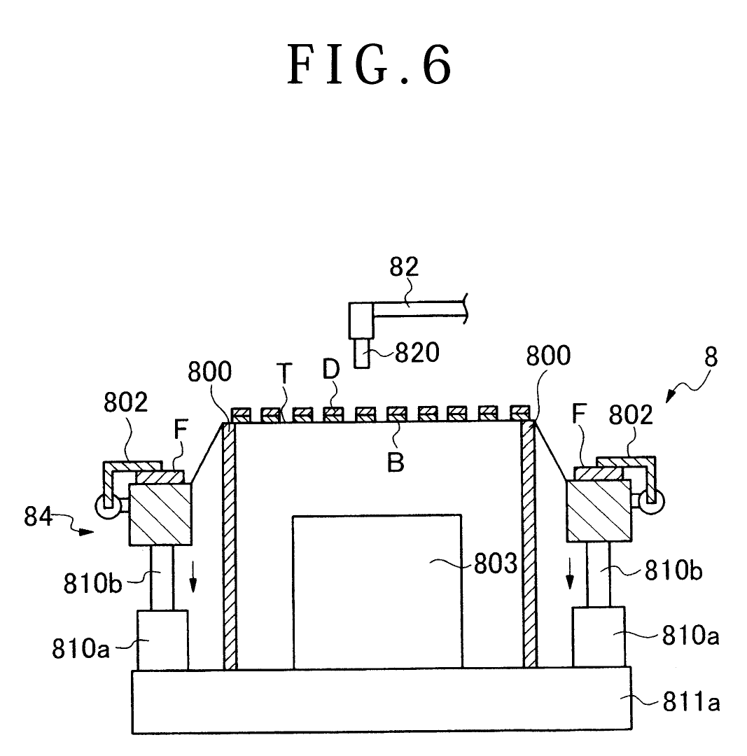

Referring to FIG. 6, while not changing the position of the die support base 800, the pistons 810b are moved downward to lower the frame support means 801 to thereby lower the frame F, which stretches the dicing tape T. This breaks the cut-residual portions B1 (see FIG. 3) left in the bonding film B so that the bonding film B is divided for each die. As a result, the bonding film B is stuck to the rear surface of each of the dice D and to the dicing tape T. In this case, the die support base 800, the frame support means 801 and the lifting drive portion 810 constitute a tape stretching means 84 for stretching the dicing tape T to break the bonding film B.

With the dicing tape T stretched as described above, the imaging portion 83 next detects a die to be picked up. The suction portion 820 of the pickup bonding portion 82 is moved to a position immediately above the die and lowered thereat, and then sucks the detected die D together with the bonding film B. The suction portion 820 is lifted while sucking the die D, thus, peeling off and picking up, from the dicing tape T, the die D with the bonding film B stuck to the rear surface. In this case, if the bonding film B is made to have a temperature of e.g. 10° C. or lower by applying cooling air thereto from the cooling means 803 or by other means, the picking-up can be done more smoothly. Alternatively, a needle-like bar may be used to push up a die to be picked up via the dicing tape T, thereby making it easy to peel off the die.

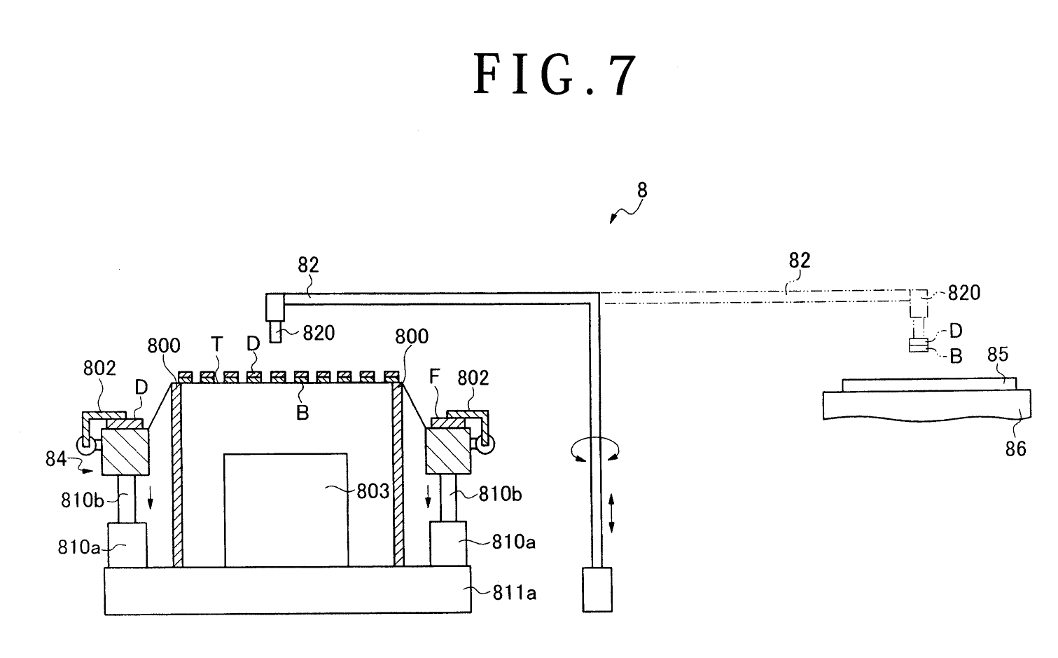

Referring to FIG. 7, the die bonder 8 is equipped with a holding portion 86 which holds a mount-targeted substrate such as a lead frame or the like and can move in a horizontal direction. The die D sucked and picked up by the suction portion 820 is moved to a predetermined position of the substrate 85 by the turning and lowering of the pickup bonding portion 82. In the state where the substrate 85 is located at the predetermined position by the forward, rearward, leftward and rightward movement of the suction portion 820, the suction portion 820 is lowered and releases the suction so that the die D is die-bonded to the substrate 85 at the predetermined position via the bonding film B. All the dice D stuck to the dicing tape T are each picked up and soon die-bonded to the substrate 85 as it is.

In this way, in the state where the interval between the dice D is expanded by the stretch of the dicing tape, the die D picked up is transferred as it is and die-bonded to the substrate. Thus, it is possible to prevent the adhesion of the bonding films adjacent to each other, whereby the pickup and die-bonding can be done smoothly to improve productivity.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A die bonding method of bonding a die having a bonding film on a rear surface thereof to a substrate, comprising:
a bonding film sticking step of sticking the bonding film to a rear surface of a wafer in which a plurality of the dice are formed and sectioned by predetermined dividing lines;
a support step of sticking the bonding film to a dicing tape whose outer circumferential portion is stuck to a dicing frame to support the wafer by the dicing frame;
a cutting step of completely cutting the predetermined dividing line and incompletely cutting the bonding film to leave a cut-residual portion;
a breaking step of stretching the dicing tape to break the cut-residual portion of the bonding film;
a picking-up step of picking up from the dicing tape the die to which the bonding film is stuck; and
a die bonding step of bonding the die thus picked up to the substrate.

2. The die bonding method according to claim 1, wherein the cutting step is executed by a cutting blade or a laser beam.

3. The die bonding method according to claim 1, wherein the cut-residual portion of the bonding film has a thickness of 20 μm or less in the cutting step.

4. The die bonding method according to claim 1, wherein the bonding film is cooled to 10° C. or lower in the picking-up step.

5. A die bonder for picking up and bonding a die to a mount-targeted substrate, the die having a bonding film stuck to a rear surface thereof and supported by a dicing frame to which the bonding film is stuck, comprising:
frame supporting means for supporting the dicing frame;
tape stretching means for stretching the dicing tape to break the bonding film;
cooling means for cooling the bonding film; and
a picking-up and bonding portion for picking-up from the stretched dicing tape the die to which the bonding film is stuck and bonding the die to the mount-targeted substrate.
